(19) United States
(12) Patent Application Publication
(10) Pub. No.: US 2008/0063901 A1
(43) Pub. Date: Mar. 13, 2008

(54) MAGNETIC RECORDING MEDIUM, MAGNETIC RECORDING MEDIUM MANUFACTURING APPARATUS, AND METHOD OF MANUFACTURING A MAGNETIC RECORDING MEDIUM

(75) Inventors: Masao NAKAYAMA, Tokyo (JP); Hiromichi KANAZAWA, Tokyo (JP); Shigeharu WATASE, Tokyo (JP); Takahiro HAYASHI, Tokyo (JP)

Correspondence Address: GREENBLUM & BERNSTEIN, P.L.C., 1950 ROLAND CLARKE PLACE, RESTON, VA, 20191, US

(73) Assignee: TDK CORPORATION, Tokyo (JP)

(21) Appl. No.: 11/851,611

(22) Filed: Sep. 7, 2007

(30) Foreign Application Priority Data
Sep. 8, 2006 (JP) 2006-243495

(51) Int. Cl. G11B 5/66; C23C 14/14

(52) U.S. Cl. 428/827; 427/531

(57) ABSTRACT

A magnetic recording medium includes a first metal thin-film magnetic layer and a second metal thin-film magnetic layer, which respectively include a plurality of columns and have magnetization easy axes that are inclined in opposite directions, formed in that order on a non-magnetic substrate. Both metal thin-film magnetic layers include former growth portions that comprise base end parts of the respective columns and latter growth portions that comprise remaining parts of the respective columns on front-end sides of the columns. The former growth portions are formed by the columns growing in a thickness direction of the non-magnetic substrate. The latter growth portions are formed by the columns growing so as to become inclined to a length of the non-magnetic substrate and arc-shaped in profile.

### BACKGROUND OF THE INVENTION

1. Field of the Invention

The present invention relates to a magnetic recording medium on which a first metal thin-film magnetic layer and a second metal thin-film magnetic layer, whose magnetization easy axes are inclined in opposite directions, are formed in the mentioned order on a non-magnetic substrate and to a method of manufacturing a magnetic recording medium and a magnetic recording medium manufacturing apparatus for manufacturing such magnetic recording medium.

2. Description of the Related Art

Due to the increasing size of recorded data, it is necessary to increase the recording density of current information media. Many magnetic tapes marketed as backup media are so-called “wet-coating type magnetic recording media” where the saturation magnetization falls corresponding to the amount of binder (i.e., resin material) included in the magnetic layer to bind the magnetic powder. The included amount of binder also makes it difficult to make the magnetic layer thinner, which results in a larger diameter when the magnetic tape is wound. Accordingly, for a wet-coating type magnetic recording medium, it is difficult to make the recording density significantly higher and also difficult to fit a long magnetic recording medium into the limited enclosed space inside a cartridge case.

On the other hand, a “evaporated magnetic recording medium” where a magnetic layer is formed by depositing a magnetic material on a non-magnetic substrate in a vacuum is known as one example of a magnetic recording medium where a magnetic layer is formed without including a binder. With this evaporated magnetic recording medium, since columns that construct the magnetic layer (i.e., aggregates of crystal grains of the magnetic material) grow so as to become inclined to the non-magnetic substrate, the magnetization easy axis of the magnetic layer becomes inclined by a predetermined angle to the longitudinal direction of the main surface of the magnetic recording medium. Accordingly, with an evaporated magnetic recording medium, the magnetic characteristics will differ according to the direction in which the tape is running and there is a large difference in the signal level of the output signal, which makes bidirectional recording and reproducing difficult. Evaporated magnetic recording media with various constructions have been proposed to solve this problem.

In Japanese Laid-Open Patent Publication No. H11-328645, for example, a tape-type magnetic recording medium is disclosed where a first magnetic layer and a second magnetic layer are formed in the mentioned order on one surface of a non-magnetic substrate. Both magnetic layers are formed as thin films of a metal material with cobalt (Co) as a main component according to a thin-film forming method such as vacuum deposition. With this magnetic recording medium, when metal material is obliquely deposited on the non-magnetic substrate (i.e., when columns are obliquely grown on the non-magnetic substrate) to form both magnetic layers, the magnetization easy axis of the first magnetic layer is inclined by a predetermined angle to one direction along the longitudinal direction of the main surface of the magnetic recording medium and the magnetization easy axis of the second magnetic layer is inclined by a predetermined angle to the other direction along the longitudinal direction of the main surface of the magnetic recording medium so that both magnetic layers are formed with magnetization easy axes that do not have the same orientation. Since the magnetization easy axes of the magnetic layers are inclined in opposite directions, this magnetic recording medium is not susceptible to differences in the magnetization characteristics and/or in the signal level of the output signal being produced due to differences in the running direction of the tape. Accordingly, bidirectional recording and reproducing are possible for this magnetic recording medium.

### SUMMARY OF THE INVENTION

However, by investigating the conventional magnetic recording medium, the present inventors found the following problem. With the conventional magnetic recording medium, both magnetic layers are formed by obliquely depositing metal material on the non-magnetic substrate. As shown in FIG. 8, with a non-magnetic substrate 2x (for example, a polymer film) used for this type of magnetic recording medium, extremely small concaves Z1ax and convexes Z1bx are formed on the surface on which the magnetic layers will be formed (i.e., the upper surface in FIG. 8) so as to produce concaves and convexes in the tape surface (i.e., the surface of a magnetic layer or a protective layer formed thereupon) with a sufficient size to reduce the friction during the running of the tape. Such concaves and convexes are formed in the non-magnetic substrate 2x with the intention of having concaves and convexes of substantially the same size as the concaves Z1ax and convexes Z1bx of the non-magnetic substrate 2x produced in the tape surface when the magnetic layers and the like are formed. Note that in the following description, reference numerals that refer to component elements of the conventional magnetic recording medium are indicated by the suffix “x”. With some non-magnetic substrates, a layer of resin material in which filler, for example, has been mixed is formed on the opposite surface of the non-magnetic substrate to the surface on which the magnetic layer will be formed (i.e., on the surface of the non-magnetic substrate on which the back coat layer will be formed), with concaves and convexes also being formed in such surface of the non-magnetic substrate to improve the running characteristics of the non-magnetic substrate during the manufacturing of a magnetic recording medium (i.e., to improve the running characteristics of the magnetic recording medium until the formation of the back coat layer has been completed). When this type of non-magnetic substrate is tightly wound, there are cases where the convexes out of such concaves and convexes formed in the surface on which the back coat layer will be formed are transferred to the surface on which the magnetic layers will be formed, thereby forming concaves and convexes in the surface on which the magnetic layers will be formed.

When a metal material is obliquely deposited on the non-magnetic substrate 2x in a state where concaves and convexes have been produced, as shown in FIG. 8 it will be difficult for the metal material to adhere to some parts of the concaves Z1ax on the non-magnetic substrate 2x (in more detail, to the inclined surfaces on the downstream sides of the concaves Z1ax or inclined surfaces on the upstream sides of the convexes Z1bx during the depositing of metal material), so that concaves Z2ax that are deeper than the concaves Z1ax of the non-magnetic substrate 2 and convexes Z2bx that are higher than the convexes Z1bx will be formed in the first magnetic layer 3x during the growth process of the columns (i.e., during the formation process of the first magnetic layer 3x). As a result of the metal material being obliquely deposited at positions where the concaves Z2ax and convexes Z2bx have been produced, as shown by the dashed line in FIG. 8, concaves Z3ax that are even deeper than the concaves Z2ax and convexes Z3bx that are even higher than the convexes Z2bx are formed in the surface of the first magnetic layer 3x. This means that large concaves and convexes are produced in the surface of the first magnetic layer 3x. Accordingly, when a second magnetic layer (not shown) has been formed by obliquely depositing metal material on the first magnetic layer 3x in this state, concaves that are significantly deeper than the concaves Z3ax formed in the surface of the first magnetic layer 3x and convexes that are significantly higher than the convexes Z3bx formed in the surface of the first magnetic layer 3x are formed in the second magnetic layer, which means that large concaves and convexes are produced in the surface of the second magnetic layer.

This means that with the conventional magnetic recording medium, due to the production of large concaves and convexes in the surface of the second magnetic layer, during the recording and reproducing of data, a large spacing loss is produced between a recording/reproducing head and the surface of the second magnetic layer. Accordingly, with the conventional magnetic recording medium, there are the problems of deterioration in the magnetization characteristics of both magnetic layers and of a large fall in the signal level of an output signal during the reading of a magnetic signal.

The present invention was conceived in view of the problems described above and it is an object of the present invention to provide a magnetic recording medium that has a higher recording density, that is capable of bidirectional recording and reproducing and for which spacing loss can be avoided during recording and reproducing, and also to provide a magnetic recording medium manufacturing apparatus and a method of manufacturing a magnetic recording medium capable of manufacturing such magnetic recording medium.

A magnetic recording medium according to the present invention includes a first metal thin-film magnetic layer and a second metal thin-film magnetic layer, which respectively include a plurality of columns and have magnetization easy axes that are inclined in opposite directions, formed in the mentioned order on a non-magnetic substrate, wherein both metal thin-film magnetic layers include former growth portions that comprise base end parts of the respective columns and latter growth portions that comprise remaining parts of the respective columns on front-end sides of the columns, the former growth portions are formed by the columns growing in a thickness direction of the non-magnetic substrate, and the latter growth portions are formed by the columns growing so as to become inclined to a longitudinal direction of the non-magnetic substrate and arc-shaped in profile. Note that the expression “thickness direction” for the present invention does not mean only the direction of a normal to the non-magnetic substrate and includes directions that are inclined in a range of around 10° to a normal to the non-magnetic substrate.

According to this magnetic recording medium, by including the first metal thin-film magnetic layer and the second metal thin-film magnetic layer that respectively include the former growth portions that are formed of parts where the columns have grown in the thickness direction of the non-magnetic substrate (i.e., base end parts of the columns) and the latter growth portions that are formed of parts where the columns have grown so as to become inclined to a longitudinal direction of the non-magnetic substrate and arc-shaped in profile (i.e., the front-end parts of the columns), forming the former growth portions in the first metal thin-film magnetic layer makes it possible to form the first metal thin-film magnetic layer with the desired smoothness, and in turn the first metal thin-film magnetic layer having the desired smoothness makes it possible to avoid deterioration in the smoothness of the second metal thin-film magnetic layer formed on the first metal thin-film magnetic layer. Also, even if extremely small concaves and convexes that could not be absorbed by forming the former growth portions in the first metal thin-film magnetic layer are present in the surface of the first metal thin-film magnetic layer, forming the former growth portions in the second metal thin-film magnetic layer will still make it possible to form the second metal thin-film magnetic layer with the desired smoothness. Accordingly, unlike a magnetic recording medium manufactured according to the conventional method of manufacturing, it is possible to produce extremely small concaves and convexes that can reduce the friction (i.e., concaves and convexes of substantially the same size as the concaves and convexes formed in advance in the surface of the non-magnetic substrate) while sufficiently improving the overall smoothness of the magnetic recording medium to a level where the occurrence of spacing loss is avoided. As a result, it is possible to sufficiently improve both the signal level of the output signal when the tape is running forwards and the signal level of the output signal when the tape is running in reverse while avoiding deterioration in the tape running characteristics during recording and reproducing.

With this magnetic recording medium, a ratio of a thickness of the first metal thin-film magnetic layer to a thickness of the second metal thin-film magnetic layer may be in a rang of 0.60 to 2.10, inclusive (in other words, the ratio of the thickness of the second metal thin-film magnetic layer to the thickness of the first metal thin-film magnetic layer may be in a range of 0.48 to 1.67, inclusive).

With this construction, it is possible to make the signal level of the output signal from a magnetic head substantially equal when the tape is running both forwards and in reverse during bidirectional recording and reproducing. Since it is possible to reproduce recorded data without a large change in the recording/reproducing conditions between when the tape is running forwards and when the tape is running in reverse, it is possible to sufficiently reduce the manufacturing cost of a recording/reproducing apparatus by an amount corresponding to the simplification of recording/reproducing control.

With this magnetic recording medium, a ratio of a thickness of the former growth portions to a thickness of the latter growth portions may be in a range of 0.08 to 0.15, inclusive in both metal thin-film magnetic layers (in other words, a ratio of a thickness of the latter growth portions to a thickness of the former growth portions may be in a range of 6.67 to 12.50, inclusive).

With this construction, it is possible to provide a magnetic recording medium with a sufficiently high coercivity. By doing so, it is also possible to maintain a sufficient magnetization state for recorded data to be read properly even when the width of the data recording tracks is reduced and/or the length of one bit on each data recording track is reduced to increase the recording density (a state where the influence of adjacent bits in the track width direction and/or the track length direction becomes prominent).

A magnetic recording medium manufacturing apparatus according to the present invention includes: a rotating cooling drum that drives a non-magnetic substrate placed around a circumferential surface thereof while cooling the non-magnetic substrate; a crucible that holds a metal material; an electron gun that emits an electron beam toward the metal material inside the crucible to vaporize the metal material; and a mask that is disposed along the circumferential surface of the rotating cooling drum and determines a deposition region where the metal material is deposited on the non-magnetic substrate, wherein the magnetic recording medium manufacturing apparatus manufactures a magnetic recording medium by twice carrying out a depositing process that deposits the metal material on the non-magnetic substrate inside the deposition region to form a first metal thin-film magnetic layer and a second metal thin-film magnetic layer, which respectively include a plurality of columns and have magnetization easy axes that are inclined in opposite directions, in the mentioned order on the non-magnetic substrate, the magnetic recording medium manufacturing apparatus further includes an oxygen gas supplying unit that supplies oxygen gas to a deposition start point in the deposition region, and during each depositing process, columns grow in a thickness direction of the non-magnetic substrate by supplying the oxygen gas from the oxygen gas supplying unit to the deposition start point to form former growth portions composed of base end parts of the respective columns, and from the deposition start point to a deposition end point in the deposition region, the columns grow so as to become inclined to a longitudinal direction of the non-magnetic substrate and arc-shaped in profile to form latter growth portions composed of remaining parts of the respective columns on the front-end sides of the columns.

A method of manufacturing a magnetic recording medium according to the present invention manufactures a magnetic recording medium by forming a first metal thin-film magnetic layer and a second metal thin-film magnetic layer, which respectively include a plurality of columns and have magnetization easy axes that are inclined in opposite directions, in the mentioned order on a non-magnetic substrate by running the non-magnetic substrate around a circumferential surface of a rotating cooling drum and twice carrying out a depositing process that deposits vaporized metal material on the non-magnetic substrate within a deposition region set on the circumferential surface of the rotating cooling drum to consecutively form both metal thin-film magnetic layers, wherein during each depositing process, the columns grow in a thickness direction of the non-magnetic substrate by supplying oxygen gas to a deposition start point in the deposition region to form former growth portions composed of base end parts of the columns, and from the deposition start point to a deposition end point, the columns grow so as to become inclined to a longitudinal direction of the non-magnetic substrate and arc-shaped in profile to form latter growth portions composed of remaining parts of the columns on the front-end sides of the columns.

According to this magnetic recording medium manufacturing apparatus and method of manufacturing a magnetic recording medium, by consecutively forming the first metal thin-film magnetic layer and the second metal thin-film magnetic layer by forming the former growth portions formed of base end parts of the columns by supplying oxygen gas to the deposition start point of the deposition region to grow the columns in the thickness direction of the non-magnetic substrate and forming the latter growth portions formed of the remaining parts (i.e., front end parts) of the columns by growing the columns from the deposition start point to the deposition end point so as to become inclined to the longitudinal direction of the non-magnetic substrate and arc-shaped in profile, it is possible to reliably and easily manufacture a magnetic recording medium where the ratios of the thicknesses of the former growth portions to the thicknesses of the latter growth portions is in the desired range, or in other words, a magnetic recording medium with the desired smoothness.

It should be noted that the disclosure of the present invention relates to a content of Japanese Patent Application 2006-243495 that was filed on 8 Sep. 2006 and the entire content of which is herein incorporated by reference.

### BRIEF DESCRIPTION OF THE DRAWINGS

These and other objects and features of the present invention will be explained in more detail below with reference to the attached drawings, wherein:

FIG. 1 is a cross-sectional view of a magnetic tape in the longitudinal direction;

FIG. 2 is a schematic view showing the construction of a manufacturing apparatus;

FIG. 3 is a cross-sectional view of a non-magnetic substrate in a state where a first magnetic layer has been formed;

FIG. 4 is a cross-sectional view of the non-magnetic substrate in a state where a second magnetic layer has been formed on the first magnetic layer shown in FIG. 3;

FIG. 5 is a cross-sectional view of the non-magnetic substrate in a state where a protective layer has been formed on the second magnetic layer shown in FIG. 4;

FIG. 6 is a table showing the coercivity and the output difference (an absolute value) between the forward output and the reverse output of magnetic tapes of Examples 1 to 17 and Comparative Examples 1 to 3;

FIG. 7 is a table showing the supplied amounts of oxygen (i.e., manufacturing conditions) when manufacturing the respective magnetic tapes of Examples 1 to 17 and Comparative Examples 1 to 3; and

FIG. 8 is a cross-sectional view useful in explaining a state where a first magnetic layer has been formed on a non-magnetic substrate when manufacturing a conventional magnetic recording medium.

### DESCRIPTION OF THE PREFERRED EMBODIMENTS

Preferred embodiments of a magnetic recording medium, a magnetic recording medium manufacturing apparatus, and a method of manufacturing a magnetic recording medium according to the present invention will now be described with reference to the attached drawings.

First, the construction of a magnetic tape 1 that is one example of a magnetic recording medium according to the present invention will be described with reference to the drawings.

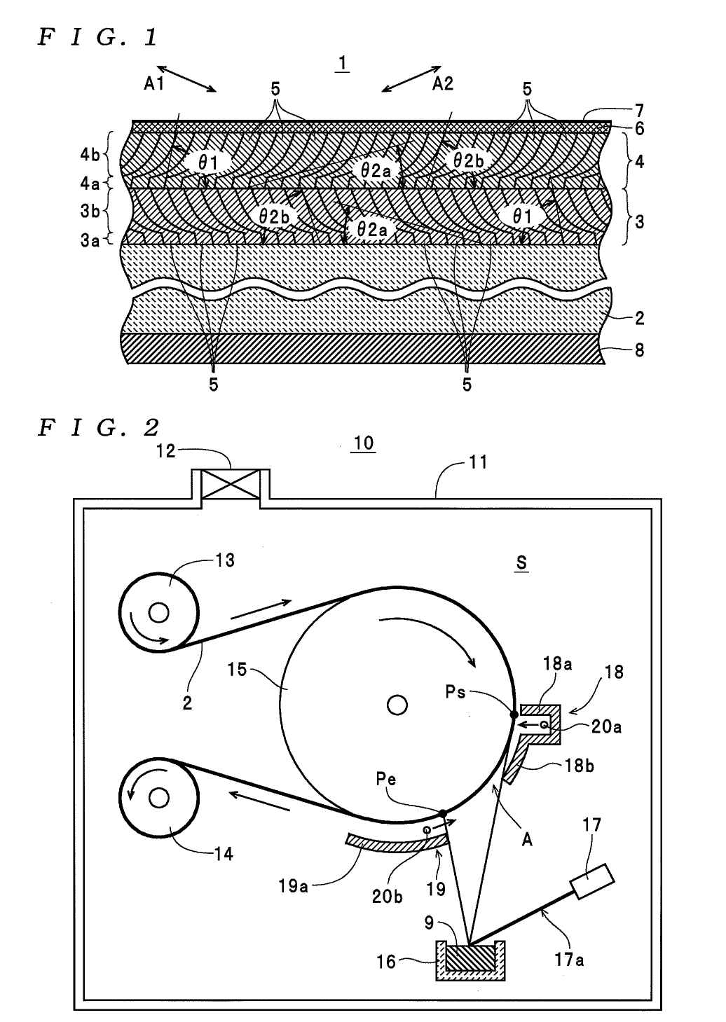

The magnetic tape 1 shown in FIG. 1 is constructed by forming a first magnetic layer 3, a second magnetic layer 4, and a protective layer 6 in the mentioned order on one surface (the upper surface in FIG. 1) of a non-magnetic substrate 2 and forming a back coat layer 8 on the other surface (the lower surface in FIG. 1) of the non-magnetic substrate 2. A lubricant 7 is also applied onto the surface of the protective layer 6. The non-magnetic substrate 2 is formed of a film of a non-magnetic material (as one example, a polymer material) capable of withstanding the heat applied during the formation processes of the magnetic layers 3, 4 and during the formation process of the protective layer 6, described later. As specific examples, the non-magnetic substrate 2 is formed of various types of polymer material such as polyethylene terephthalate (PET), polyethylene naphthalate (PEN), polyamide, polyamide-imide, and polyimide. Here, as one example, the non-magnetic substrate 2 of the magnetic tape 1 is constructed of a polyethylene-2,6-naphthalate (PEN) film with a thickness of 4.7 μm.

As described later, extremely small concaves and convexes are formed in the surface of the non-magnetic substrate 2 (i.e., the surface on which the magnetic layers 3, 4 will be formed) so as to produce concaves and convexes in the surfaces of the magnetic layers 3, 4 and the protective layer 6 to reduce the friction thereof. Concaves and convexes for improving the running characteristics of the non-magnetic substrate 2 during the manufacturing of the magnetic recording medium (i.e., to improve the running characteristics of the magnetic recording medium until the formation of the back coat layer 8 has been completed) are also formed in the rear surface of the non-magnetic substrate 2 (i.e., on the opposite surface of the non-magnetic substrate 2 to the surface on which the magnetic layers 3, 4 will be formed: in other words, on the surface of the non-magnetic substrate 2 on which the back coat layer 8 will be formed). Accordingly, when this type of non-magnetic substrate 2 is tightly wound, there are cases where the convexes out of the concaves and convexes formed in the rear surface of the non-magnetic substrate 2 are transferred to the front surface (i.e., the surface on which the magnetic layers 3, 4 will be formed), thereby forming concaves and convexes in the front surface.

The first magnetic layer 3 corresponds to the “first metal thin-film magnetic layer” for the present invention and as described later is constructed by forming a plurality of columns 5 by depositing a ferromagnetic metal material 9 (see FIG. 2) in a vacuum on one surface of the non-magnetic substrate 2 by oblique evaporation. Here, the ferromagnetic metal material 9 corresponds to the “metal material” for the present invention and as examples, Co (cobalt) or a Co alloy that includes cobalt as a main component is used since it is possible to obtain favorable magnetic characteristics, the material cost is comparatively low, and the material is also harmless. Note that to form a magnetic layer with magnetic characteristics suited to recording and reproducing data, the proportion (i.e., percentage content) of Co expressed relative to all of the metal elements included in the ferromagnetic metal material 9 should preferably be at least 60 atomic %, more preferably at least 80 atomic %, and especially at least 90 atomic %. Here, when a Co alloy is used as the ferromagnetic metal material 9, it is preferable to use an alloy with Co and Ni as main components or an alloy with Co, Ni, and Cr as main components, and the percentage content of the respective elements aside from Co in such alloys can be selected as appropriate in accordance with the magnetic characteristics and corrosion resistance required for the magnetic layers.

The first magnetic layer 3 is constructed by consecutively forming former growth portions 3a that comprise respective base end parts of the columns 5 (i.e., the parts of the columns 5 on the non-magnetic substrate 2 side) and latter growth portions 3b that comprise the remaining parts of the columns 5 (i.e., front-end parts or the parts of the columns 5 on the protective layer 6 side) in the mentioned order from the non-magnetic substrate 2 side. Here as described later, the former growth portions 3a are parts that also function as an underlayer to improve the smoothness of the first magnetic layer 3 (i.e., parts that prevent deterioration in the smoothness of the first magnetic layer 3) and are composed of parts where the columns 5 linearly grow in the thickness direction of (i.e., substantially perpendicular to) the non-magnetic substrate 2 during the former stage of a deposition process that deposits the ferromagnetic metal material 9 on the non-magnetic substrate 2 (i.e., during a formation process of the first magnetic layer 3). Note that the expression “in the thickness direction of (i.e., substantially perpendicular to) the non-magnetic substrate 2” given above includes directions that are inclined in a range of around 0° to 10° to a normal to the non-magnetic substrate 2, or in other words, directions with an inclination angle θ1 of around 90° to 80° with respect to the surface of the non-magnetic substrate 2. The applicant has confirmed that when the inclination angle θ1 with respect to the surface of the non-magnetic substrate 2 is below 80°, there is deterioration in the smoothness of the first magnetic layer 3.

The former growth portions 3a are formed as follows. As described later, during the formation process of the first magnetic layer 3, due to oxygen gas being supplied from a start point oxygen supplying unit 18 provided in the vicinity of a deposition start point Ps of a deposition region A (see FIG. 2) where the ferromagnetic metal material 9 will be deposited on the non-magnetic substrate 2, the vaporized ferromagnetic metal material 9 will adhere to the surface of the non-magnetic substrate 2 in a state where the ferromagnetic metal material 9 has been sufficiently mixed with oxygen gas at the deposition start point Ps. Accordingly, the columns 5 are formed so as to grow linearly in the thickness direction of (i.e., substantially perpendicular to) the non-magnetic substrate 2. Also, since the ferromagnetic metal material 9 adheres to the non-magnetic substrate 2 having been mixed with oxygen gas supplied from an oxygen supplying pipe 20a, the former growth portions 3a are formed with Co—O as the main component. When doing so, the amount of oxygen included in the former growth portions 3a should preferably be around 50 atomic % to 60 atomic %.

The thickness of the former growth portions 3a should preferably be in a range of 3 nm to 50 nm, inclusive. If the thickness is in this range of 3 nm to 50 nm, inclusive, it is possible for the base end parts of the columns 5 (i.e., the parts that construct the former growth portions 3a) to grow sufficiently finely and uniformly. Accordingly, it is also possible for the front end parts of the columns 5 (i.e., the parts that construct the latter growth portions 3b) that grow after the former growth portions 3a to grow sufficiently finely and uniformly. In addition, by setting the thickness of the former growth portions 3a in the range of 3 nm to 50 nm, inclusive, it will be easy to align the c axis orientations of the Co (hexagonal crystals) in the columns 5 in the latter growth portions 3b that are formed after the former growth portions 3a (i.e., easy to align the origins of crystal magnetic anisotropy). By doing so, the latter growth portions 3b can have sufficiently high coercivity and sufficiently high remanent magnetization, and as a result, it is possible to achieve a sufficiently high C/N ratio. Also, by setting the thickness of the former growth portions 3a in the range of 3 nm to 50 nm, inclusive, even when concaves and convexes are present in the surface of the non-magnetic substrate 2, it will be possible to form concaves and convexes of substantially the same size as the concaves and convexes of the non-magnetic substrate 2 in the surface of the first magnetic layer 3 without causing deterioration in the smoothness of the first magnetic layer 3.

On the other hand, when the thickness of the former growth portions 3a is below 3 nm, it is difficult to make the base end parts of the columns 5 grow uniformly and finely. Accordingly, there is the risk that it will be difficult to make the front end parts of the columns 5 also grow uniformly and finely after the former growth portions 3a have been formed. In addition, when the thickness of the former growth portions 3a is below 3 nm, there is the risk that the c axis orientations of the Co (hexagonal crystals) in the columns 5 in the latter growth portions 3b will not be aligned (i.e., that the origins of crystal magnetic anisotropy will not be aligned). Accordingly, since there is a fall in the coercivity and remanent magnetization of the latter growth portions 3b, there is the risk that it will be difficult to achieve a high C/N ratio. Also, if the thickness of the former growth portions 3a is below 3 nm, there is the risk when concaves and convexes are present in the surface of the non-magnetic substrate 2 that larger concaves and convexes will be formed in the surface of the first magnetic layer 3.

On the other hand, when the thickness of the former growth portions 3a is above 50 nm, there is the risk that the columns 5 will grow too large in both the plane and the thickness directions of the first magnetic layer 3, resulting in large concaves and convexes being produced at the boundaries between the former growth portions 3a and the latter growth portions 3b. This would result in the risk of large concaves and convexes being produced in the surface of the latter growth portions 3b, that is, in the surface of the first magnetic layer 3. Also, when the thickness of the former growth portions 3a is above 50 nm, there is the risk of the winding diameter of the magnetic tape 1 becoming too large due to the first magnetic layer 3 being too thick. Note that for the magnetic tape 1, as one example the thickness of the former growth portions 3a in the first magnetic layer 3 is set at 7 nm.

The latter growth portions 3b are composed of parts formed by causing the columns 5 to continuously grow on the former growth portions 3a during the process that deposits the ferromagnetic metal material 9 on the non-magnetic substrate 2 (i.e., the formation process of the first magnetic layer 3). That is, the latter growth portions 3b are composed of the respective front end parts of the columns 5. More specifically, the latter growth portions 3b are composed of parts produced by causing the columns 5 (i.e., the parts that construct the former growth portions 3a) that have grown on the non-magnetic substrate 2 during the former stage of the deposition process for the ferromagnetic metal material 9 to further grow so as to become inclined to the longitudinal direction of the non-magnetic substrate 2 and arc-shaped in profile. Note that the first magnetic layer 3x of the conventional magnetic recording medium has the same construction as when only these latter growth portions 3b are formed.

With the magnetic tape 1, as described later, the non-magnetic substrate 2 is run around the circumferential surface of a rotating cooling drum 15 (see FIG. 2) while depositing the ferromagnetic metal material 9 to form the first magnetic layer 3. Accordingly, the inclination angle θ2a of parts formed at positions that are adjacent to the deposition start point Ps on the deposition end point Pe side of the deposition region A in which the ferromagnetic metal material 9 is deposited on the non-magnetic substrate 2 (i.e., the inclination angle θ2a of the base ends of the latter growth portions 3b of the columns 5) will be in a range of around 10° to 60°, the inclination angle θ2a will gradually increase, and the inclination angle θ2b of the parts formed near the deposition end point Pe of the deposition region A (i.e., the inclination angle θ2b of the front ends of the latter growth portions 3b of the columns 5) will become the maximum (in a range of around 30° to 90°), so that the parts that construct the latter growth portions 3b of the columns 5 become arc-shaped in profile.

The latter growth portions 3b are formed with Co as the main component and include a smaller amount of oxygen than the former growth portions 3a described earlier. Here, the amount of oxygen included in the latter growth portions 3b should preferably be in a range of 20 atomic % to 50 atomic %. Also, the thickness of the latter growth portions 3b should preferably be in a range of 10 nm to 300 nm, inclusive. If the thickness is in this range, the parts that construct the latter growth portions 3b (i.e., the front end parts) formed following the parts that construct the former growth portions 3a (i.e., the base end parts) of the columns 5 can grow sufficiently finely and uniformly, and therefore it is possible to sufficiently improve the smoothness of the surface of the latter growth portions 3b (that is, the surface of the first magnetic layer 3). By doing so, it is possible to reduce the spacing loss between the magnetic tape 1 and the magnetic head during recording and reproducing, and as a result, it is possible to achieve a sufficiently high C/N ratio.

On the other hand, when the thickness of the latter growth portions 3b is below 10 nm, there is the risk that it will be difficult to achieve sufficiently high levels for the coercivity and remanent magnetization of the latter growth portions 3b. On the other hand, when the thickness of the latter growth portions 3b exceeds 300 nm, the parts that construct the latter growth portions 3b of the columns 5 (i.e., the front end parts) will grow excessively in both the plane and the thickness directions of the first magnetic layer 3, resulting in deterioration in the smoothness of the latter growth portions 3b and an increase in the spacing loss during recording and reproducing. Accordingly, there is the risk of difficulty in achieving a high C/N ratio. Note that for the magnetic tape 1, as one example the thickness of the latter growth portions 3b of the first magnetic layer 3 is set at 68 nm.

In this way, when a construction is used where the former growth portions 3a are formed inside the first magnetic layer 3, in view of the combination of a sufficient thickness to obtain the various effects described above due to the formation of the former growth portions 3a and a sufficient thickness to obtain the various effects described above due to the formation of the latter growth portions 3b, the thickness of the latter growth portions 3b should preferably be greater than the thickness of the former growth portions 3a. More specifically, the thicknesses of the former growth portions 3a and the latter growth portions 3b should preferably be set so that the ratio of the thickness of the former growth portions 3a to the thickness of the latter growth portions 3b is in a range of 0.08 to 0.15, inclusive (in this example, 0.10). Note that the relationship between the ratio of the thickness of the former growth portions 3a to the thickness of the latter growth portions 3b and the recording/reproducing characteristics of the magnetic tape 1 will be described in detail later in this specification.

The second magnetic layer 4 corresponds to the “second metal thin-film magnetic layer” for the present invention and as shown in FIG. 1, the second magnetic layer 4 is constructed by forming a plurality of columns 5 by depositing the ferromagnetic metal material 9 (see FIG. 2) in a vacuum on the first magnetic layer 3 formed on the non-magnetic substrate 2 by oblique evaporation. Note that since the ferromagnetic metal material 9 used to form the second magnetic layer 4 is the same as the ferromagnetic metal material 9 used to form the first magnetic layer 3 described above, duplicated description thereof is omitted.

The second magnetic layer 4 is constructed by consecutively forming former growth portions 4a that comprise respective base end parts of the columns 5 described above (i.e., the parts of the columns 5 on the non-magnetic substrate 2 side) and latter growth portions 4b that comprise the remaining parts of the columns 5 (i.e., front end parts or the parts of the columns 5 on the protective layer 6 side) in the mentioned order from the non-magnetic substrate 2 side on top of the first magnetic layer 3. Here, as described later and in the same way as the former growth portions 3a of the first magnetic layer 3 described earlier, the former growth portions 4a are parts that also function as an underlayer to improve the smoothness of the second magnetic layer 4 (i.e., parts that prevent deterioration in the smoothness of the second magnetic layer 4) and are constructed by causing the columns 5 to linearly grow in the thickness direction of (i.e., substantially perpendicular to) the non-magnetic substrate 2 during a former stage of the deposition process (i.e., the formation process of the second magnetic layer 4) of the ferromagnetic metal material 9.

Note that the expression “in the thickness direction of (i.e., substantially perpendicular to) the non-magnetic substrate 2” given above includes directions that are inclined in a range of around 0° to 10° to a normal to the non-magnetic substrate 2, or in other words, directions with an inclination angle θ1 of around 90° to 80° with respect to the surface of the non-magnetic substrate 2. The applicant has confirmed that when the inclination angle θ with respect to the surface of the non-magnetic substrate 2 is below 80°, there is deterioration in the smoothness of the second magnetic layer 4.

Like the former growth portions 3a of the first magnetic layer 3 described earlier, since the former growth portions 4a are formed by supplying oxygen gas from the start point oxygen supplying unit 18 provided in the vicinity of the deposition start point Ps (see FIG. 2) of the deposition region A where the ferromagnetic metal material 9 will be deposited, the vaporized ferromagnetic metal material 9 will adhere to the surface of the first magnetic layer 3 in a state where the ferromagnetic metal material 9 has been sufficiently mixed with oxygen gas at the deposition start point Ps. Accordingly, the columns 5 are formed so as to grow linearly in the thickness direction of (i.e., substantially perpendicular to) the non-magnetic substrate 2. Also, since the ferromagnetic metal material 9 adheres to the first magnetic layer 3 having been mixed with oxygen gas supplied from an oxygen supplying pipe 20a, the former growth portions 4a are formed with Co—O as the main component. When doing so, the amount of oxygen included in the former growth portions 4a should preferably be around 50 atomic % to 60 atomic %. The thickness of the former growth portions 4a should preferably be in a range of 3 nm to 50 nm, inclusive for the same reasons as the thickness of the former growth portions 3a described earlier. Note that for the magnetic tape 1, as one example the thickness of the former growth portions 4a in the second magnetic layer 4 is set at 7 nm.

Like the latter growth portions 3b of the first magnetic layer 3, the latter growth portions 4b are composed of parts formed by continuously growing the columns 5 on the former growth portions 4a during the process that deposits the ferromagnetic metal material 9 (i.e., the formation process of the second magnetic layer 4). That is, the latter growth portions 4b are composed of the respective front end parts of the columns 5. More specifically, the latter growth portions 4b are composed of parts produced by causing the columns 5 (i.e., the parts that construct the former growth portions 4a) that have grown on the first magnetic layer 3 in the former stage of the deposition process for the ferromagnetic metal material 9 to further grow so as to become inclined to the longitudinal direction of the non-magnetic substrate 2 and arc-shaped in profile. Note that in the same way as the latter growth portions 3b, the inclination angle θ2a of the base end parts of the columns 5 is in a range of around 10° to 60°, the inclination angle θ2a gradually increases, and the inclination angle θ2b of the front end parts of the columns 5 becomes the maximum (in a range of around 30° to 90°), so that the parts that construct the latter growth portions 4b of the columns 5 become arc-shaped in profile. Note that the second magnetic layer of the conventional magnetic recording medium has the same construction as when only these latter growth portions 4b are formed.

The latter growth portions 4b are formed with Co as the main component and include a smaller amount of oxygen than the former growth portions 4a described earlier. Here, the amount of oxygen included in the latter growth portions 4b should preferably be in a range of 20 atomic % to 50 atomic %. Also, for the same reasons as the thickness of the latter growth portions 3b of the first magnetic layer 3 described earlier, the thickness of the latter growth portions 4b should preferably be in the range of 10 nm to 300 nm, inclusive. Note that for the magnetic tape 1, as one example the thickness of the latter growth portions 4b of the second magnetic layer 4 is set at 65 nm.

In this way, when a construction is used where the former growth portions 4a are formed inside the second magnetic layer 4, in view of the combination of a sufficient thickness to obtain the various effects described above due to the formation of the former growth portions 4a and a sufficient thickness to obtain the various effects described above due to the formation of the latter growth portions 4b, the thickness of the latter growth portions 4b should preferably be greater than the thickness of the former growth portions 4a. More specifically, the thicknesses of the former growth portions 4a and the latter growth portions 4b should preferably be set so that the ratio of the thickness of the former growth portions 4a to the thickness of the latter growth portions 4b is in a range of 0.08 to 0.15, inclusive (in this example, 0.11). Note that the relationship between the ratio of the thickness of the former growth portions 4a to the thickness of the latter growth portions 4b and the recording/reproducing characteristics of the magnetic tape 1 will be described in detail later.

With the magnetic tape 1, as shown in FIG. 1, the first magnetic layer 3 and the second magnetic layer 4 are formed so that the parts that construct the latter growth portions 3b of the columns 5 in the first magnetic layer 3 and the parts that construct the latter growth portions 4b of the columns 5 in the second magnetic layer 4 are inclined in opposite directions with respect to the thickness direction of (i.e., along a normal to) the non-magnetic substrate 2. Accordingly, with the magnetic tape 1, the orientation of the magnetization easy axis of the first magnetic layer 3 (i.e., the orientation shown by the arrow A1 in FIG. 1) and the orientation of the magnetization easy axis of the second magnetic layer 4 (i.e., the orientation shown by the arrow A2 in FIG. 1) are inclined in opposite directions, which as described later, prevents differences in the magnetization characteristics and differences in the signal level of the output signal from appearing when bidirectional recording is carried out on the magnetic tape 1. With the magnetic tape 1, the first magnetic layer 3 and the second magnetic layer 4 are formed so that the ratio of the thickness of the first magnetic layer 3 to the thickness of the second magnetic layer 4 is in a range of 0.60 to 2.10, inclusive (in this example, 1.04). By doing so, the difference in the signal levels of the output signals when bidirectional recording is carried out on the magnetic tape 1 is sufficiently reduced.

The protective layer 6 is a thin film that prevents oxidization of the magnetic layers 3, 4 described above and also prevents abrasion of the magnetic layers 3, 4, and as one example is formed of DLC (Diamond Like Carbon). As examples of the lubricant 7, a lubricant that includes fluorine, a hydrocarbon series ester, or a mixture of the same is used. The back coat layer 8 is formed with a thickness in a range of around 0.1 μm to 0.7 μm by applying and hardening a back coat layer coating composition produced by mixing and dispersing a binder resin (binder) and an inorganic compound and/or carbon black in an organic solvent. Here, it is possible to use any of a vinyl chloride copolymer, polyurethane resin, acrylic resin, epoxy resin, phenoxy resin, and polyester resin, or a mixture of the same, as the binder resin. As the carbon black, it is possible to use furnace carbon black, thermal carbon black, or the like, and as the inorganic compound, it is possible to use calcium carbonate, alumina, α-iron oxide or the like. In addition, as the organic solvent, it is possible to use a ketone or aromatic hydrocarbon solvent (for example, methyl ethyl ketone, toluene, and cyclohexanone).

Next, the construction of a magnetic tape manufacturing apparatus 10 constructed so as to be capable of manufacturing the magnetic tape 1 described above and the method of manufacturing the magnetic tape 1 will be described with reference to the drawings.

The magnetic tape manufacturing apparatus (hereinafter simply “manufacturing apparatus”) 10 shown in FIG. 2 corresponds to a “magnetic recording medium manufacturing apparatus” according to the present invention and is constructed by enclosing a feed roll 13, a winding roll 14, the rotating cooling drum 15, a crucible 16, an electron gun 17, the start point oxygen supplying unit 18, and an end point oxygen supplying unit 19 inside a vacuum chamber 11 and is constructed so as to be capable of forming both the magnetic layers 3, 4 described above. A vacuum pump 12 for evacuating air in the internal space S to maintain a vacuum is attached to the vacuum chamber 11.

The feed roll 13 rotates a roll into which the non-magnetic substrate 2 (on which the first magnetic layer 3 or the second magnetic layer 4 is to be formed) has been wound to feed the non-magnetic substrate 2 toward the rotating cooling drum 15. The winding roll 14 winds the non-magnetic substrate 2, on which the first magnetic layer 3 or the second magnetic layer 4 has been formed, into a roll. The rotating cooling drum 15 drives the non-magnetic substrate 2 fed from the feed roll 13 around the circumferential surface thereof while cooling the non-magnetic substrate 2. Note that although in reality, guide rollers and the like are present between the feed roll 13 and the rotating cooling drum 15 and between the rotating cooling drum 15 and the winding roll 14, for ease of understanding the present invention, such parts have been omitted from the drawings and this description.

The crucible 16 is formed of MgO or the like, for example, and stores the ferromagnetic metal material 9 (in this example, Co) that is regularly supplied by a material supplying apparatus, not shown. The crucible 16 is positioned so that the ferromagnetic metal material 9 that is vaporized by irradiation with an electron beam 17a outputted from the electron gun 17 is obliquely deposited on the surface of the non-magnetic substrate 2 running around the circumferential surface of the rotating cooling drum 15. The electron gun 17 outputs the electron beam 17a to vaporize the ferromagnetic metal material 9 inside the crucible 16.

The start point oxygen supplying unit 18 includes an oxygen mixing chamber 18a, a mask 18b, and an oxygen supplying pipe 20a and is disposed upstream in the running direction of the non-magnetic substrate 2. The oxygen mixing chamber 18a is formed in a box-like shape whose length in the width direction of the non-magnetic substrate 2 (i.e., perpendicular to the plane of the paper in FIG. 2) that is running around the circumferential surface of the rotating cooling drum 15 is slightly larger than the width of the non-magnetic substrate 2, and is disposed so that an open side of the oxygen mixing chamber 18a faces the circumferential surface of the rotating cooling drum 15 (i.e., faces the surface of the non-magnetic substrate 2). The width of the oxygen mixing chamber 18a (i.e., the length of the opening in the running direction of the non-magnetic substrate 2) is set in accordance with various conditions, such as the thicknesses of the former growth portions 3a, 4a to be formed in the first magnetic layer 3 and the second magnetic layer 4, the diameter of the rotating cooling drum 15, and the running speed of the non-magnetic substrate 2.

The oxygen supplying pipe 20a disposed inside the oxygen mixing chamber 18a supplies oxygen gas to the deposition start point Ps end of the deposition region A. The oxygen supplying pipe 20a is constructed by forming a plurality of oxygen gas supply openings (as examples, round holes and/or slits) along the width of the non-magnetic substrate 2. The applicant has found that by disposing the oxygen mixing chamber 18a near the deposition start point Ps and mixing the ferromagnetic metal material 9 vaporized from the crucible 16 with the oxygen gas supplied from the oxygen supplying pipe 20a inside the oxygen mixing chamber 18a to disperse the vaporized component of the ferromagnetic metal material 9 in the oxygen gas, the former growth portions 3a, 4a are formed due to the columns 5 that grow on the non-magnetic substrate 2 linearly growing in the thickness direction of (i.e., along a normal or substantially perpendicular to) the non-magnetic substrate 2.

The mask 18b prevents the ferromagnetic metal material 9 vaporized from the crucible 16 from adhering to the non-magnetic substrate 2 (by covering the non-magnetic substrate 2) to set the deposition start point Ps of the deposition region A. By adjusting the disposed position of the mask 18b relative to the rotating cooling drum 15, the maximum angle at which the ferromagnetic metal material 9 adheres to the non-magnetic substrate 2 (here, an angle between a normal for the non-magnetic substrate 2 in the part to which the ferromagnetic metal material 9 adheres and the direction in which the crucible 16 is present as viewed from the part to which the ferromagnetic metal material 9 adheres) is set.

The end point oxygen supplying unit 19 includes a mask 19a and an oxygen supplying pipe 20b, and is disposed downstream in the running direction of the non-magnetic substrate 2. The mask 19a prevents the ferromagnetic metal material 9 vaporized from the crucible 16 from adhering to the non-magnetic substrate 2 (by covering the non-magnetic substrate 2) to set the deposition end point Pe of the deposition region A. Also, by adjusting the disposed position of the mask 19a relative to the rotating cooling drum 15, the minimum angle at which the ferromagnetic metal material 9 adheres to the non-magnetic substrate 2 (here, an angle between a normal for the non-magnetic substrate 2 and the direction in which the crucible 16 is present as viewed from the part to which the ferromagnetic metal material 9 adheres) is set.

The oxygen supplying pipe 20b is disposed between the mask 19a and the rotating cooling drum 15 and is disposed near the deposition end point Pe end of the deposition region A described above. The oxygen supplying pipe 20b is constructed by forming a plurality of oxygen gas supply openings (as examples, round holes and/or slits) along the width of the non-magnetic substrate 2. Here, the oxygen gas supplied by the end point gas supplying unit 19 is introduced with the aim of improving the saturation flux density, coercivity, and electromagnetic conversion characteristics of the first magnetic layer 3 and the second magnetic layer 4 being formed.

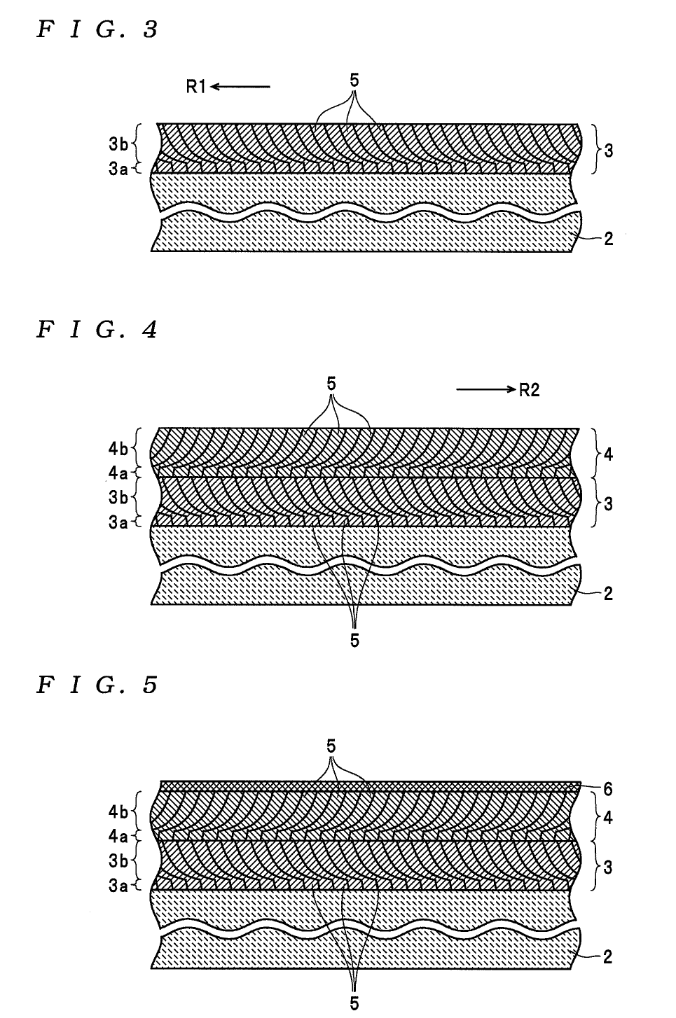

On the other hand, when manufacturing the magnetic tape 1, by using the manufacturing apparatus 10, the first magnetic layer 3 is formed on the non-magnetic substrate 2 as shown in FIG. 3 and then the second magnetic layer 4 is formed on the formed first magnetic layer 3 as shown in FIG. 4. That is, by twice carrying out a depositing process that deposits ferromagnetic metal material 9 on the non-magnetic substrate 2, the first magnetic layer 3 and the second magnetic layer 4 are formed in the mentioned order on the non-magnetic substrate 2.

More specifically, first an original roll, which has been produced by winding the non-magnetic substrate 2 on which the first magnetic layer 3 will be formed, is set on the feed roll 13, the non-magnetic substrate 2 is placed around the circumferential surface of the rotating cooling drum 15, and the end of the non-magnetic substrate 2 is fixed to the winding roll 14. Next, after the vacuum pump 12 has been driven to evacuate the vacuum chamber 11 to a pressure of around 10⁻³ Pa, the feed roll 13, the winding roll 14, and the rotating cooling drum 15 are rotated to run the non-magnetic substrate 2 around the circumferential surface of the rotating cooling drum 15. After this, the ferromagnetic metal material 9 is vaporized by emitting the electron beam 17a from the electron gun 17 toward the ferromagnetic metal material 9 inside the crucible 16 and the supplying of oxygen gas from the oxygen supplying pipes 20a, 20b is commenced. When doing so, the electron gun 17 scans the electron beam 17a (i.e., moves the electron beam 17a right and left) with a predetermined pitch in the width direction of the non-magnetic substrate 2. By doing so, the ferromagnetic metal material 9 is heated and vaporized inside the crucible 16.

When doing so, out of the ferromagnetic metal material 9 vaporized from the crucible 16, a large amount of the ferromagnetic metal material 9 that reaches the vicinity of the deposition start point Ps becomes mixed with the oxygen gas supplied from the oxygen supplying pipe 20a inside the oxygen mixing chamber 18a. The ferromagnetic metal material 9 mixed with the oxygen gas collides with the oxygen gas, thereby changing the direction in which the ferromagnetic metal material 9 moves to a variety of directions. As a result, the ferromagnetic metal material 9 accumulates on and adheres to the non-magnetic substrate 2 running around the circumferential surface of the rotating cooling drum 15. By doing so, the base end parts of the columns 5 that construct the first magnetic layer 3 grow on the non-magnetic substrate 2 so that the formation of the former growth portions 3a of the first magnetic layer 3 proceeds.

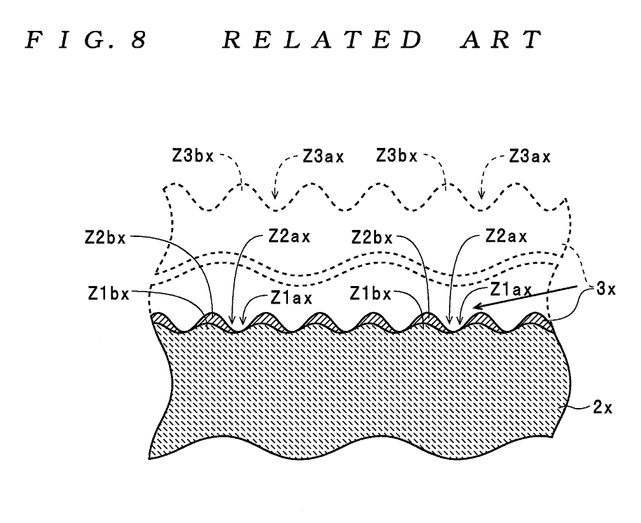

If the ferromagnetic metal material 9 is caused to adhere to the non-magnetic substrate 2 using a typical conventional method of oblique evaporation, when extremely small concaves and convexes are present in the surface of the non-magnetic substrate 2, it will be difficult for the ferromagnetic metal material 9 to adhere to the upstream sides of the convexes (the convexes Z1bx in FIG. 8) in the running direction of the non-magnetic substrate 2 and the ferromagnetic metal material 9 will adhere to only the downstream sides of the convexes in the running direction. Accordingly, with conventional oblique evaporation, as described earlier when extremely small concaves and convexes are present on the non-magnetic substrate 2, convexes appear on the surface of the first magnetic layer 3 with an exaggerated (enlarged) size. This results in a tendency for deterioration in the smoothness of the first magnetic layer 3.

On the other hand, with the manufacturing apparatus 10 where the ferromagnetic metal material 9 adheres to the non-magnetic substrate 2 in a state where the ferromagnetic metal material 9 has been mixed with oxygen gas in the vicinity of the deposition start point Ps, mixing the ferromagnetic metal material 9 that was vaporized from the crucible 16 with the oxygen gas inside the oxygen mixing chamber 18a results in the ferromagnetic metal material 9 adhering to the non-magnetic substrate 2 in directions that are unrelated to the direction in which the ferromagnetic metal material 9 has arrived from the crucible 16. Accordingly, the ferromagnetic metal material 9 adheres in the thickness direction of (i.e., along a normal or substantially perpendicular to) the non-magnetic substrate 2, resulting in the base end parts of the columns 5 growing linearly to form the former growth portions 3a on the non-magnetic substrate 2. Therefore, even if extremely small concaves and convexes are present in the surface of the non-magnetic substrate 2, the ferromagnetic metal material 9 will adhere in the same way to both the upstream sides and the downstream sides of the convexes in the running direction of the non-magnetic substrate 2. As a result, a situation where larger concaves and convexes than the concaves and convexes of the non-magnetic substrate 2 are formed during the formation of the former growth portions 3a is avoided and concaves and convexes of substantially the same size as the concaves and convexes of the non-magnetic substrate 2 are formed in the surface of the first magnetic layer 3.

Note that the expression “deposition start point Ps” in this specification refers to a deposition start point in geometric terms that is set based on the relationship between the position of the crucible 16 and the position of the rotating cooling drum 15, and that in reality, there are cases where in accordance with the size of the oxygen mixing chamber 18a, the amount of oxygen gas fed from the oxygen supplying pipe 20a, and the vaporized amount of the ferromagnetic metal material 9, deposition of the ferromagnetic metal material 9 on the non-magnetic substrate 2 starts further upstream than the deposition start point Ps shown in FIG. 2.

After the former growth portions 3a have been formed at the position of the start point oxygen supplying unit 18, the non-magnetic substrate 2 runs around the circumferential surface of the rotating cooling drum 15 and moves to an area between the masks 18b, 19a. When doing so, since the ferromagnetic metal material 9 that has been vaporized and emitted from the crucible 16 adheres to the former growth portions 3a described above (i.e., the base end parts of the columns 5), during the period until the non-magnetic substrate 2 reaches the deposition end point Pe, the latter growth portions 3b are formed on the former growth portions 3a due to the columns 5 continuously growing from the base end parts (i.e., the parts that construct the former growth portions 3a). During the period from immediately after the non-magnetic substrate 2 becomes exposed from the mask 18b until when the non-magnetic substrate 2 is covered by the mask 19a, the direction in which the crucible 16 is positioned relative to the non-magnetic substrate 2 (i.e., the direction in which the ferromagnetic metal material 9 reaches the non-magnetic substrate 2 from the crucible 16) constantly changes, and as a result, as shown in FIG. 3, the front end parts of the columns 5 (i.e., the parts that construct the latter growth portions 3b) grow so as to become inclined toward the downstream side in the running direction of the non-magnetic substrate 2 and arc-shaped in profile. Note that in FIG. 3, a state where the non-magnetic substrate 2 is running in the direction of the arrow R1 is shown.

By forming the former growth portions 3a on the non-magnetic substrate 2, even if concaves and convexes are present in the surface of the non-magnetic substrate 2, during the formation of the former growth portions 3a such concaves and convexes will be covered by the ferromagnetic metal material 9 and oxide thereof so that the degree (size) of the concaves and convexes is sufficiently reduced. Accordingly, a situation where concaves and convexes that are larger than the concaves and convexes present in the surface of the non-magnetic substrate 2 are formed during the formation of the latter growth portions 3b that are formed on the former growth portions 3a is avoided, and as a result concaves and convexes of substantially the same size as the concaves and convexes present in the surface of the non-magnetic substrate 2 are formed in the surface of the latter growth portions 3b, that is, in the surface of the first magnetic layer 3. By doing so, a first magnetic layer 3 with the desired smoothness is formed on the non-magnetic substrate 2. The thickness of the latter growth portions 3b can be set at a desired thickness by appropriately adjusting the position of the mask 19a, the running speed of the non-magnetic substrate 2, and the vaporized amount of the ferromagnetic metal material 9.

Note that like the deposition start point Ps described earlier, the “deposition end point Pe” described above refers to a geometric deposition end point and that in reality, due to the running speed of the non-magnetic substrate 2, the vaporized amount of the ferromagnetic metal material 9, and/or the ferromagnetic metal material 9 getting behind the mask 19a, there are cases where deposition of the ferromagnetic metal material 9 on the non-magnetic substrate 2 continues further downstream than the deposition end point Pe shown in FIG. 2.

After this, the non-magnetic substrate 2 on which the formation of the former growth portions 3a and the latter growth portions 3b has been completed (i.e., the formation of the first magnetic layer 3 has been completed) is separated from the circumferential surface of the rotating cooling drum 15 and is wound onto the winding roll 14. By doing so, the first out of the two deposition processes for the present invention is completed.

Next, an original roll produced by winding the non-magnetic substrate 2 on which the formation of the first magnetic layer 3 has been completed is set on the feed roll 13, the non-magnetic substrate 2 is placed around the circumferential surface of the rotating cooling drum 15, and the end of the non-magnetic substrate 2 is fixed to the winding roll 14. Next, after the vacuum pump 12 has been driven to evacuate the vacuum chamber 11, the feed roll 13, the winding roll 14, and the rotating cooling drum 15 are rotated to run the non-magnetic substrate 2 around the circumferential surface of the rotating cooling drum 15. When doing so, the non-magnetic substrate 2 runs in the opposite direction to the formation process of the first magnetic layer 3 described earlier. Next, the ferromagnetic metal material 9 is vaporized by emitting the electron beam 17a from the electron gun 17 toward the ferromagnetic metal material 9 inside the crucible 16 and the supplying of oxygen gas from the oxygen supplying pipes 20a, 20b is commenced.

When doing so, in the same way as the formation process of the former growth portions 3a and the latter growth portions 3b described earlier, the former growth portions 4a and the latter growth portions 4b are formed on the first magnetic layer 3 as shown in FIG. 4. Note that in FIG. 4, the state where the non-magnetic substrate 2 is running in the direction of the arrow R2 is shown. Here, in the same way as the former growth portions 3a described earlier, by forming the former growth portions 4a on the first magnetic layer 3 during a former stage (i.e., in the vicinity of the oxygen mixing chamber 18a) during the formation process for the second magnetic layer 4, even if concaves and convexes are present on the surface of the first magnetic layer 3, the concaves and convexes will be covered with the ferromagnetic metal material 9 and the oxide thereof during the formation process of the former growth portions 4a, so that the degree (i.e., size) of the concaves and convexes can be sufficiently reduced. Accordingly, a situation where larger concaves and convexes than the concaves and convexes of the first magnetic layer 3 are formed during the formation of the latter growth portions 4b formed on the former growth portions 4a is avoided and as a result, concaves and convexes of substantially the same size as the concaves and convexes of the first magnetic layer 3 are formed in the surface of the latter growth portions 4b, that is, in the surface of the second magnetic layer 4. By doing so, a second magnetic layer 4 with the desired smoothness is formed on the first magnetic layer 3. After this, the non-magnetic substrate 2 on which the formation of the former growth portions 4a and the latter growth portions 4b has been completed (i.e., the formation of the second magnetic layer 4 has been completed) is separated from the circumferential surface of the rotating cooling drum 15 and is wound onto the winding roll 14. By doing so, the second out of the two deposition processes for the present invention is completed.

After this, as shown in FIG. 5, a protective layer forming apparatus (not shown) is used to form the protective layer 6 by causing DLC to adhere to the surface of the second magnetic layer 4. Next, by applying the back coat layer coating composition to the rear surface side of the non-magnetic substrate 2 and drying the back coat layer coating composition, the back coat layer 8 is formed. The lubricant 7 is applied onto the surface of the protective layer 6. In this way, a series of manufacturing processes for the magnetic tape 1 is completed and as shown in FIG. 1, the magnetic tape 1 is completed. Note that although the magnetic tape to be enclosed in a tape cartridge as the final product is manufactured by cutting the non-magnetic substrate 2 onto which the lubricant 7 has been applied into predetermined tape widths, for ease of understanding the present invention, description and illustration of such process have been omitted.

Next, the relationship between the presence/absence of the former growth portions 3a, 4a, the ratio of the thickness of the first magnetic layer 3 to the thickness of the second magnetic layer 4, the ratios of the thicknesses of the former growth portions 3a, 4a to the thicknesses of the latter growth portions 3b, 4b, and the recording/reproducing characteristics of the magnetic tape will be described in detail with respect to Examples and Comparative Examples.

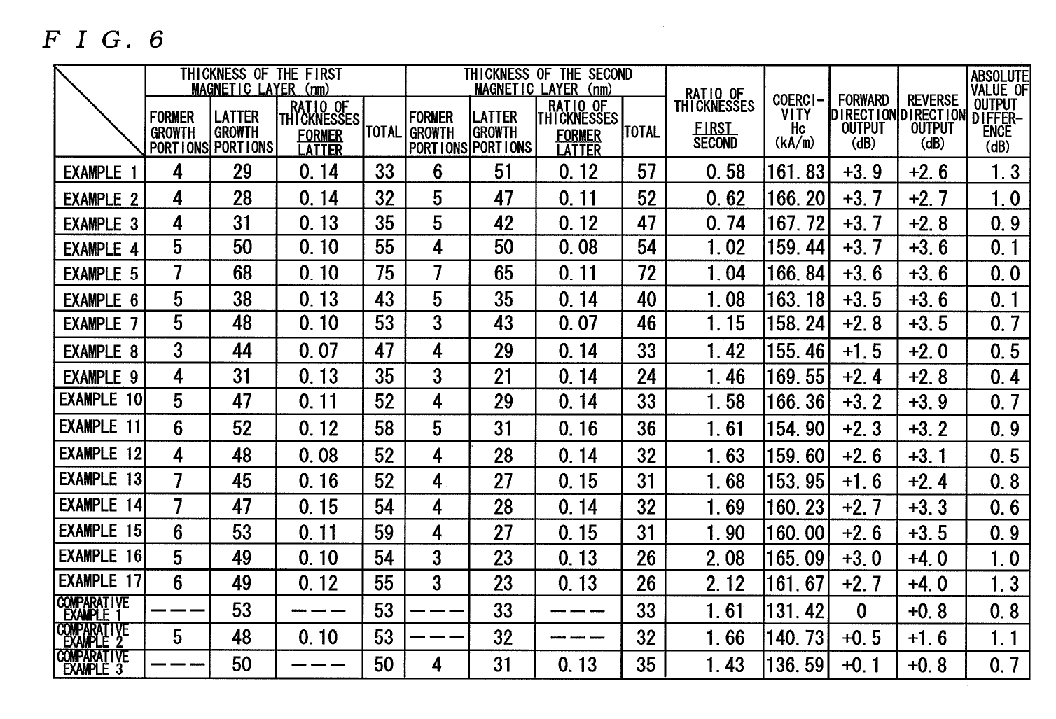

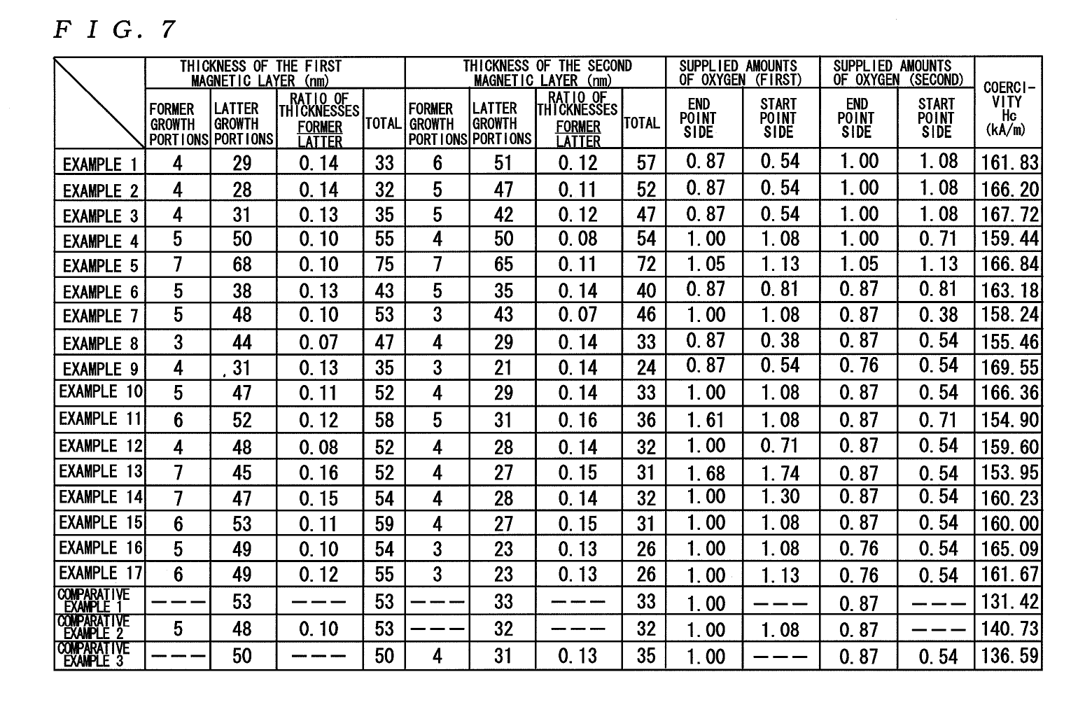

First, magnetic tapes of Examples 1 to 17 and magnetic tapes of Comparative Examples 1 to 3 shown in FIGS. 6 and 7 were manufactured using the manufacturing apparatus 10 described above. Here, the method of manufacturing the respective magnetic tapes was fundamentally the same as for the magnetic tape 1 described above. Note that the amounts of oxygen gas supplied from the oxygen supplying pipes 20a, 20b when forming the first magnetic layer and the second magnetic layer are shown in FIG. 7. Here, in FIG. 7, the amount of oxygen gas supplied from the oxygen supplying pipe 20a during the formation of the former growth portions of the first magnetic layer, the amount of oxygen gas supplied from the oxygen supplying pipe 20b during the formation of the latter growth portions of the first magnetic layer, the amount of oxygen gas supplied from the oxygen supplying pipe 20a during the formation of the former growth portions of the second magnetic layer, and the amount of oxygen gas supplied from the oxygen supplying pipe 20b during the formation of the latter growth portions of the second magnetic layer are expressed as proportions with the amount of oxygen gas supplied from the oxygen supplying pipe 20b at the deposition end point Pe during the formation of the first magnetic layer of Comparative Example 1 as the standard amount.

### Example 1

The first magnetic layer and the second magnetic layer were formed in the mentioned order on the non-magnetic substrate 2 so that the thickness of the former growth portions of the first magnetic layer was 4 nm, the thickness of the latter growth portions of the first magnetic layer was 29 nm, the thickness of the former growth portions of the second magnetic layer was 6 nm, and the thickness of the latter growth portions of the second magnetic layer was 51 nm. As a result, the thickness of the first magnetic layer was 33 nm and the thickness of the second magnetic layer was 57 nm, so that the ratio of the thickness of the first magnetic layer to the thickness of the second magnetic layer was 0.58. Also, the ratio of the thickness of the former growth portions to the thickness of the latter growth portions of the first magnetic layer was 0.14 and the ratio of the thickness of the former growth portions to the thickness of the latter growth portions of the second magnetic layer was 0.12.

### Example 2

The first magnetic layer and the second magnetic layer were formed in the mentioned order on the non-magnetic substrate 2 so that the thickness of the former growth portions of the first magnetic layer was 4 nm, the thickness of the latter growth portions of the first magnetic layer was 28 nm, the thickness of the former growth portions of the second magnetic layer was 5 nm, and the thickness of the latter growth portions of the second magnetic layer was 47 nm. As a result, the thickness of the first magnetic layer was 32 nm and the thickness of the second magnetic layer was 52 nm, so that the ratio of the thickness of the first magnetic layer to the thickness of the second magnetic layer was 0.62. Also, the ratio of the thickness of the former growth portions to the thickness of the latter growth portions of the first magnetic layer was 0.14 and the ratio of the thickness of the former growth portions to the thickness of the latter growth portions of the second magnetic layer was 0.11.

### Example 3

The first magnetic layer and the second magnetic layer were formed in the mentioned order on the non-magnetic substrate 2 so that the thickness of the former growth portions of the first magnetic layer was 4 nm, the thickness of the latter growth portions of the first magnetic layer was 31 nm, the thickness of the former growth portions of the second magnetic layer was 5 nm, and the thickness of the latter growth portions of the second magnetic layer was 42 nm. As a result, the thickness of the first magnetic layer was 35 nm and the thickness of the second magnetic layer was 47 nm, so that the ratio of the thickness of the first magnetic layer to the thickness of the second magnetic layer was 0.74. Also, the ratio of the thickness of the former growth portions to the thickness of the latter growth portions of the first magnetic layer was 0.13 and the ratio of the thickness of the former growth portions to the thickness of the latter growth portions of the second magnetic layer was 0.12.

### Example 4

The first magnetic layer and the second magnetic layer were formed in the mentioned order on the non-magnetic substrate 2 so that the thickness of the former growth portions of the first magnetic layer was 5 nm, the thickness of the latter growth portions of the first magnetic layer was 50 nm, the thickness of the former growth portions of the second magnetic layer was 4 nm, and the thickness of the latter growth portions of the second magnetic layer was 50 nm. As a result, the thickness of the first magnetic layer was 55 nm and the thickness of the second magnetic layer was 54 nm, so that the ratio of the thickness of the first magnetic layer to the thickness of the second magnetic layer was 1.02. Also, the ratio of the thickness of the former growth portions to the thickness of the latter growth portions of the first magnetic layer was 0.10 and the ratio of the thickness of the former growth portions to the thickness of the latter growth portions of the second magnetic layer was 0.08.

### Example 5

### The Magnetic Tape 1 Described Earlier

The first magnetic layer and the second magnetic layer were formed in the mentioned order on the non-magnetic substrate 2 so that the thickness of the former growth portions of the first magnetic layer was 7 nm, the thickness of the latter growth portions of the first magnetic layer was 68 nm, the thickness of the former growth portions of the second magnetic layer was 7 nm, and the thickness of the latter growth portions of the second magnetic layer was 65 nm. As a result, the thickness of the first magnetic layer was 75 nm and the thickness of the second magnetic layer was 72 nm, so that the ratio of the thickness of the first magnetic layer to the thickness of the second magnetic layer was 1.04. Also, the ratio of the thickness of the former growth portions to the thickness of the latter growth portions of the first magnetic layer was 0.10 and the ratio of the thickness of the former growth portions to the thickness of the latter growth portions of the second magnetic layer was 0.11.

### Example 6

The first magnetic layer and the second magnetic layer were formed in the mentioned order on the non-magnetic substrate 2 so that the thickness of the former growth portions of the first magnetic layer was 5 nm, the thickness of the latter growth portions of the first magnetic layer was 38 nm, the thickness of the former growth portions of the second magnetic layer was 5 nm, and the thickness of the latter growth portions of the second magnetic layer was 35 nm. As a result, the thickness of the first magnetic layer was 43 nm and the thickness of the second magnetic layer was 40 nm, so that the ratio of the thickness of the first magnetic layer to the thickness of the second magnetic layer was 1.08. Also, the ratio of the thickness of the former growth portions to the thickness of the latter growth portions of the first magnetic layer was 0.13 and the ratio of the thickness of the former growth portions to the thickness of the latter growth portions of the second magnetic layer was 0.14.

### Example 7

The first magnetic layer and the second magnetic layer were formed in the mentioned order on the non-magnetic substrate 2 so that the thickness of the former growth portions of the first magnetic layer was 5 nm, the thickness of the latter growth portions of the first magnetic layer was 48 nm, the thickness of the former growth portions of the second magnetic layer was 3 nm, and the thickness of the latter growth portions of the second magnetic layer was 43 nm. As a result, the thickness of the first magnetic layer was 53 nm and the thickness of the second magnetic layer was 46 nm, so that the ratio of the thickness of the first magnetic layer to the thickness of the second magnetic layer was 1.15. Also, the ratio of the thickness of the former growth portions to the thickness of the latter growth portions of the first magnetic layer was 0.10 and the ratio of the thickness of the former growth portions to the thickness of the latter growth portions of the second magnetic layer was 0.07.

### Example 8

The first magnetic layer and the second magnetic layer were formed in the mentioned order on the non-magnetic substrate 2 so that the thickness of the former growth portions of the first magnetic layer was 3 nm, the thickness of the latter growth portions of the first magnetic layer was 44 nm, the thickness of the former growth portions of the second magnetic layer was 4 nm, and the thickness of the latter growth portions of the second magnetic layer was 29 nm. As a result, the thickness of the first magnetic layer was 47 nm and the thickness of the second magnetic layer was 33 nm, so that the ratio of the thickness of the first magnetic layer to the thickness of the second magnetic layer was 1.42. Also, the ratio of the thickness of the former growth portions to the thickness of the latter growth portions of the first magnetic layer was 0.07 and the ratio of the thickness of the former growth portions to the thickness of the latter growth portions of the second magnetic layer was 0.14.

### Example 9

The first magnetic layer and the second magnetic layer were formed in the mentioned order on the non-magnetic substrate 2 so that the thickness of the former growth portions of the first magnetic layer was 4 nm, the thickness of the latter growth portions of the first magnetic layer was 31 nm, the thickness of the former growth portions of the second magnetic layer was 3 nm, and the thickness of the latter growth portions of the second magnetic layer was 21 nm. As a result, the thickness of the first magnetic layer was 35 nm and the thickness of the second magnetic layer was 24 nm, so that the ratio of the thickness of the first magnetic layer to the thickness of the second magnetic layer was 1.46. Also, the ratio of the thickness of the former growth portions to the thickness of the latter growth portions of the first magnetic layer was 0.13 and the ratio of the thickness of the former growth portions to the thickness of the latter growth portions of the second magnetic layer was 0.14.

### Example 10

The first magnetic layer and the second magnetic layer were formed in the mentioned order on the non-magnetic substrate 2 so that the thickness of the former growth portions of the first magnetic layer was 5 nm, the thickness of the latter growth portions of the first magnetic layer was 47 nm, the thickness of the former growth portions of the second magnetic layer was 4 nm, and the thickness of the latter growth portions of the second magnetic layer was 29 nm. As a result, the thickness of the first magnetic layer was 52 nm and the thickness of the second magnetic layer was 33 nm, so that the ratio of the thickness of the first magnetic layer to the thickness of the second magnetic layer was 1.58. Also, the ratio of the thickness of the former growth portions to the thickness of the latter growth portions of the first magnetic layer was 0.11 and the ratio of the thickness of the former growth portions to the thickness of the latter growth portions of the second magnetic layer was 0.14.

### Example 11

The first magnetic layer and the second magnetic layer were formed in the mentioned order on the non-magnetic substrate 2 so that the thickness of the former growth portions of the first magnetic layer was 6 nm, the thickness of the latter growth portions of the first magnetic layer was 52 nm, the thickness of the former growth portions of the second magnetic layer was 5 nm, and the thickness of the latter growth portions of the second magnetic layer was 31 nm. As a result, the thickness of the first magnetic layer was 58 nm and the thickness of the second magnetic layer was 36 nm, so that the ratio of the thickness of the first magnetic layer to the thickness of the second magnetic layer was 1.61. Also, the ratio of the thickness of the former growth portions to the thickness of the latter growth portions of the first magnetic layer was 0.12 and the ratio of the thickness of the former growth portions to the thickness of the latter growth portions of the second magnetic layer was 0.16.

### Example 12

The first magnetic layer and the second magnetic layer were formed in the mentioned order on the non-magnetic substrate 2 so that the thickness of the former growth portions of the first magnetic layer was 4 nm, the thickness of the latter growth portions of the first magnetic layer was 48 nm, the thickness of the former growth portions of the second magnetic layer was 4 nm, and the thickness of the latter growth portions of the second magnetic layer was 28 nm. As a result, the thickness of the first magnetic layer was 52 nm and the thickness of the second magnetic layer was 32 nm, so that the ratio of the thickness of the first magnetic layer to the thickness of the second magnetic layer was 1.63. Also, the ratio of the thickness of the former growth portions to the thickness of the latter growth portions of the first magnetic layer was 0.08 and the ratio of the thickness of the former growth portions to the thickness of the latter growth portions of the second magnetic layer was 0.14.

### Example 13

The first magnetic layer and the second magnetic layer were formed in the mentioned order on the non-magnetic substrate 2 so that the thickness of the former growth portions of the first magnetic layer was 7 nm, the thickness of the latter growth portions of the first magnetic layer was 45 nm, the thickness of the former growth portions of the second magnetic layer was 4 nm, and the thickness of the latter growth portions of the second magnetic layer was 27 nm. As a result, the thickness of the first magnetic layer was 52 nm and the thickness of the second magnetic layer was 31 nm, so that the ratio of the thickness of the first magnetic layer to the thickness of the second magnetic layer was 1.68. Also, the ratio of the thickness of the former growth portions to the thickness of the latter growth portions of the first magnetic layer was 0.16 and the ratio of the thickness of the former growth portions to the thickness of the latter growth portions of the second magnetic layer was 0.15.

### Example 14

The first magnetic layer and the second magnetic layer were formed in the mentioned order on the non-magnetic substrate 2 so that the thickness of the former growth portions of the first magnetic layer was 7 nm, the thickness of the latter growth portions of the first magnetic layer was 47 nm, the thickness of the former growth portions of the second magnetic layer was 4 nm, and the thickness of the latter growth portions of the second magnetic layer was 28 nm. As a result, the thickness of the first magnetic layer was 54 nm and the thickness of the second magnetic layer was 32 nm, so that the ratio of the thickness of the first magnetic layer to the thickness of the second magnetic layer was 1.69. Also, the ratio of the thickness of the former growth portions to the thickness of the latter growth portions of the first magnetic layer was 0.15 and the ratio of the thickness of the former growth portions to the thickness of the latter growth portions of the second magnetic layer was 0.14.

### Example 15

The first magnetic layer and the second magnetic layer were formed in the mentioned order on the non-magnetic substrate 2 so that the thickness of the former growth portions of the first magnetic layer was 6 nm, the thickness of the latter growth portions of the first magnetic layer was 53 nm, the thickness of the former growth portions of the second magnetic layer was 4 nm, and the thickness of the latter growth portions of the second magnetic layer was 27 nm. As a result, the thickness of the first magnetic layer was 59 nm and the thickness of the second magnetic layer was 31 nm, so that the ratio of the thickness of the first magnetic layer to the thickness of the second magnetic layer was 1.90. Also, the ratio of the thickness of the former growth portions to the thickness of the latter growth portions of the first magnetic layer was 0.11 and the ratio of the thickness of the former growth portions to the thickness of the latter growth portions of the second magnetic layer was 0.15.

### Example 16

The first magnetic layer and the second magnetic layer were formed in the mentioned order on the non-magnetic substrate 2 so that the thickness of the former growth portions of the first magnetic layer was 5 nm, the thickness of the latter growth portions of the first magnetic layer was 49 nm, the thickness of the former growth portions of the second magnetic layer was 3 nm, and the thickness of the latter growth portions of the second magnetic layer was 23 nm. As a result, the thickness of the first magnetic layer was 54 nm and the thickness of the second magnetic layer was 26 nm, so that the ratio of the thickness of the first magnetic layer to the thickness of the second magnetic layer was 2.08. Also, the ratio of the thickness of the former growth portions to the thickness of the latter growth portions of the first magnetic layer was 0.10 and the ratio of the thickness of the former growth portions to the thickness of the latter growth portions of the second magnetic layer was 0.13.

### Example 17

The first magnetic layer and the second magnetic layer were formed in the mentioned order on the non-magnetic substrate 2 so that the thickness of the former growth portions of the first magnetic layer was 6 nm, the thickness of the latter growth portions of the first magnetic layer was 49 nm, the thickness of the former growth portions of the second magnetic layer was 3 nm, and the thickness of the latter growth portions of the second magnetic layer was 23 nm. As a result, the thickness of the first magnetic layer was 55 nm and the thickness of the second magnetic layer was 26 nm, so that the ratio of the thickness of the first magnetic layer to the thickness of the second magnetic layer was 2.12. Also, the ratio of the thickness of the former growth portions to the thickness of the latter growth portions of the first magnetic layer was 0.12 and the ratio of the thickness of the former growth portions to the thickness of the latter growth portions of the second magnetic layer was 0.13.

### Comparative Example 1

Without forming former growth portions in the first magnetic layer, the first magnetic layer was formed of only latter growth portions with a thickness of 53 nm and without forming former growth portions in the second magnetic layer, the second magnetic layer was formed of only latter growth portions with a thickness of 33 nm. As a result, the ratio of the thickness of the first magnetic layer to the thickness of the second magnetic layer was 1.61.

### Comparative Example 2

The first magnetic layer was formed with a thickness of 53 nm by forming latter growth portions with a thickness of 48 nm on former growth portions with a thickness of 5 nm and without forming former growth portions in the second magnetic layer, the second magnetic layer was formed of only latter growth portions with a thickness of 32 nm. As a result, the ratio of the thickness of the first magnetic layer to the thickness of the second magnetic layer was 1.66, and the ratio of the thickness of the former growth portions to the thickness of the latter growth portions of the first magnetic layer was 0.10.

### Comparative Example 3

Without forming former growth portions in the first magnetic layer, the first magnetic layer was formed of only latter growth portions with a thickness of 50 nm. The second magnetic layer was formed with a thickness of 35 nm by forming latter growth portions with a thickness of 31 nm on former growth portions with a thickness of 4 nm. As a result, the ratio of the thickness of the first magnetic layer to the thickness of the second magnetic layer was 1.43, and the ratio of the thickness of the former growth portions to the thickness of the latter growth portions of the second magnetic layer was 0.13.

Measurement of Coercivity Hc

The coercivity Hc was measured for the respective magnetic tapes of the Examples and the Comparative Examples described above using a VSM (Vibrating Sample Magnetometer). The measurement results are shown in FIG. 6.

Measurement of Output

The magnetic tapes of the Examples and the Comparative Examples described above were run in both the forward and reverse directions, recording was carried out at a recording wavelength of 0.4 μm using a drum tester on which a 0.16 μm-gap inductive head was mounted, reproducing was carried out using an AMR head, and the signal level (dB) of the output signal during reproducing was measured. The measurement results are shown in FIG. 6. Note that in this example, the magnetic tape is said to be running in the “forward direction” when the recording/reproducing head moves relative to the tape in the direction in which the non-magnetic substrate runs during the formation process of the second magnetic layer (the magnetic layer on the surface side) or during the formation process of a single magnetic layer, and the magnetic tape is said to be running in the “reverse direction” when the recording/reproducing head moves relative to the tape in the direction in which the non-magnetic substrate runs during the formation process of the first magnetic layer (the magnetic layer on the non-magnetic substrate 2 side). Also, in the values of the “forward direction output (dB)” and the “reverse direction output (dB)”, the forward direction output (dB) of Comparative Example 1 is expressed as 0 dB. The values of the “output difference (dB)” are expressed as absolute values of the difference between the output (dB) measured when the tape was running in the forward direction and the output (dB) measured when the tape was running in the reverse direction.

As shown in FIG. 6, with the magnetic tape of Comparative Example 1 where former growth portions are not formed in either the first magnetic layer or the second magnetic layer, the magnetic tape of Comparative Example 2 where former growth portions are not formed in the second magnetic layer, and the magnetic tape of Comparative Example 3 where former growth portions are not formed in the first magnetic layer, the coercivity Hc was extremely low at 130 kA/m to 140 kA/m or slightly over. It is believed that this is caused by the c axis orientations of the Co (hexagonal crystals) not being aligned in the columns 5 (i.e., the origins of crystal magnetic anisotropy not being aligned) when the latter growth portions are formed due to the former growth portions not having been formed in either or both of the first magnetic layer and the second magnetic layer. Also, since there is deterioration in the smoothness of the magnetic tape when the former growth portions are not formed in either or both of the first magnetic layer and the second magnetic layer, a large spacing loss is produced between the magnetic tape and the magnetic head, resulting in comparatively low values for both the output (dB) when the magnetic tape is running forward and the output (dB) when the magnetic tape is running in reverse.

On the other hand, with the magnetic tapes of Examples 1 to 17 where the former growth portions are formed in both the first magnetic layer and the second magnetic layer, the coercivity Hc is extremely high at over 150 kA/m even for the lowest value. It is believed that this effect is caused by the c axis orientations of the Co (hexagonal crystals) being aligned in the columns 5 (i.e., due to the origins of crystal magnetic anisotropy being aligned) in one direction when the latter growth portions are formed due to the former growth portions having been formed in both the first magnetic layer and the second magnetic layer. Also, since the surface of the magnetic tape can be produced with the desired smoothness due to the former growth portions being formed in both the first magnetic layer and the second magnetic layer, a large spacing loss is not produced between the magnetic tape and the magnetic head and both the output (dB) when the magnetic tape is running forward and the output (dB) when the magnetic tape is running in reverse are comparatively high values at 1.6 dB or over even for the lowest value. Accordingly, it can be understood that by forming the former growth portions in both the first magnetic layer and the second magnetic layer, it is possible to manufacture a magnetic tape with a high coercivity Hc and also a high output (dB).

Here, with the magnetic tape of Example 1 where the ratio of the thickness of the first magnetic layer to the thickness of the second magnetic layer is below 0.60, the output when the tape is running in the reverse direction is lower than the output when the tape is running in the forward direction, and as a result the output difference is 1.3 dB. Also, with the magnetic tape of Example 17 where the ratio of the thickness of the first magnetic layer to the thickness of the second magnetic layer is over 2.10, the output when the tape is running in the forward direction is lower than the output when the tape is running in the reverse direction, and as a result the output difference is 1.3 dB. On the other hand, with the respective magnetic tapes of Examples 2 to 16 where the ratio of the thickness of the first magnetic layer to the thickness of the second magnetic layer is in the range of 0.60 to 2.10, inclusive, the output in the forward direction and the output in the reverse direction are substantially equal with an output difference of 1.0 dB or below. Accordingly, it can be understood that by setting the thickness of the first magnetic layer and the thickness of the second magnetic layer so that the ratio of the thickness of the first magnetic layer to the thickness of the second magnetic layer is in the range of 0.60 to 2.10, inclusive, it is possible to manufacture a magnetic tape with a small difference between the output when the tape is running in the forward direction and the output when the tape is running in the reverse direction, i.e., a magnetic tape that is suited to bidirectional recording and reproducing.

Also, with the magnetic tapes of Examples 7, 8 where the ratio of the thickness of the former growth portions to the thickness of the latter growth portions in either the first magnetic layer or the second magnetic layer is below 0.08 and the magnetic tapes of Examples 11, 13 where the ratio of the thickness of the former growth portions to the thickness of the latter growth portions in either the first magnetic layer or the second magnetic layer is over 0.15, the coercivity Hc is slightly low at 150 kA/m or so. On the other hand, with the magnetic tapes of Examples 1 to 3, 5, 6, 9, 10, and 14 to 17 where the ratio of the thickness of the former growth portions to the thickness of the latter growth portions in both the first magnetic layer and the second magnetic layer is in a range of 0.08 to 0.15, inclusive, the coercivity Hc is extremely high in the 160 kA/m range. Also, with the magnetic tapes of Example 4 and 12, the coercivity Hc is almost 160 kA/m which is still sufficiently higher than the magnetic tapes of Comparative Examples 1 to 3 and Examples 7, 8, 11, and 13. Accordingly, it can be understood that by forming both magnetic layers 3, 4 so that the ratio of the thickness of the former growth portions to the thickness of the latter growth portions is in the range of 0.08 to 0.15, inclusive, in both the first magnetic layer and the second magnetic layer, it is possible to manufacture a magnetic tape with high coercivity Hc.

Here, the amount of oxygen gas supplied from the start point oxygen supplying unit 18 (the oxygen supplying pipe 20a) may be adjusted to form former growth portions that can satisfy the above ratio of thicknesses. More specifically, as shown in FIG. 7, if the amount of oxygen gas supplied from the end point gas supplying unit 19 during the manufacturing of Comparative Example 1 is considered the standard amount, with the magnetic tape of Example 8 where ratio of the amount of oxygen gas supplied from the start point oxygen supplying unit 18 to the standard amount (the amount of oxygen gas supplied where the amount of oxygen of Comparative Example 1 is 1) is below 0.50 during the formation of the first magnetic layer, the ratio of the former growth portions to the latter growth portions in the first magnetic layer falls below 0.80. Also, with the magnetic tape of Example 7 where the ratio of the amount of oxygen gas supplied from the start point oxygen supplying unit 18 to the standard amount is below 0.50 during the formation of the second magnetic layer, the ratio of the former growth portions to the latter growth portions in the second magnetic layer falls below 0.80.

In addition, with the magnetic tape of Example 13 where the ratio of the amount of oxygen gas supplied from the start point oxygen supplying unit 18 to the standard amount during the formation of the first magnetic layer exceeds 1.50, the ratio of the former growth portions to the latter growth portions in the first magnetic layer exceeds 0.15. In the same way, with the magnetic tape of Example 11 where the amount of oxygen gas supplied from the start point oxygen supplying unit 18 during the formation of the second magnetic layer is comparatively large, the ratio of the former growth portions to the latter growth portions in the second magnetic layer exceeds 0.15. Accordingly, it can be understood that by appropriately adjusting the amount of oxygen gas supplied from the start point oxygen supplying unit 18 during the formation of the respective magnetic layers 3, 4, it is possible to set the ratio of the thickness of the latter growth portions to the thickness of the former growth portions in the desired range and thereby manufacture a magnetic tape with a sufficiently high coercivity Hc.

In this way, according to the magnetic tape 1, by including the first magnetic layer 3 and the second magnetic layer 4 that respectively include the former growth portions 3a, 4a formed of parts (i.e., base end parts) of the columns 5 that grow in the thickness direction of (i.e., along a normal to) the non-magnetic substrate 2 and the latter growth portions 3b, 4b formed of parts (i.e., the front end parts) of the columns 5 that grow so as to become inclined to the longitudinal direction of the non-magnetic substrate 2 and arc-shaped in profile, forming the former growth portions 3a makes it possible to form the first magnetic layer 3 with the desired smoothness. By forming the first magnetic layer 3 with the desired smoothness, it is possible to avoid a situation where there is also deterioration in the smoothness of the second magnetic layer 4 formed on the first magnetic layer 3. Also, even if extremely small concaves and convexes that could not be absorbed by forming the former growth portions 3a in the first magnetic layer 3 are present in the surface of the first magnetic layer 3, forming the former growth portions 4a will still make it possible to form the second magnetic layer 4 with the desired smoothness. Accordingly, unlike a magnetic recording medium manufactured according to the conventional method of manufacturing, it is possible to produce extremely small concaves and convexes that can reduce the friction (i.e., concaves and convexes of substantially the same size as the concaves and convexes formed in advance in the surface of the non-magnetic substrate 2) while sufficiently improving the overall smoothness of the magnetic tape 1 to a level where the occurrence of spacing loss is avoided. As a result, it is possible to sufficiently improve both the signal level of the output signal when the tape is running forwards and the signal level of the output signal when the tape is running in reverse while avoiding deterioration in the tape running characteristics during recording and reproducing.

Also, according to the magnetic tape 1, by forming the magnetic layers so that the ratio of the thickness of the first magnetic layer 3 to the thickness of the second magnetic layer 4 is in the range of 0.60 to 2.10, inclusive, it is possible to make the signal level of the output signal from a magnetic head substantially equal when the tape is running both forwards and in reverse during bidirectional recording and reproducing. Since it is possible to reproduce recorded data without a large change in the recording/reproducing conditions between when the tape is running forwards and when the tape is running in reverse, it is possible to sufficiently reduce the manufacturing cost of a recording/reproducing apparatus by an amount corresponding to the simplification of recording/reproducing control.

In addition, according to the magnetic tape 1, by forming the first magnetic layer 3 and the second magnetic layer 4 so that the ratios of the thicknesses of the former growth portions 3a, 4a to the thicknesses of the latter growth portions 3b, 4b are in the range of 0.08 to 0.15, inclusive, it is possible to provide a magnetic tape with a sufficiently high coercivity. By doing so, it is also possible to maintain a sufficient magnetization state for recorded data to be read properly even when the width of the data recording tracks is reduced and/or the length of one bit on each data recording track is reduced to increase the recording density (a state where the influence of adjacent bits in the track width direction and/or the track length direction becomes prominent).

According to the magnetic tape manufacturing apparatus 10 and the method of manufacturing the magnetic tape 1 using the manufacturing apparatus 10, by consecutively forming the first magnetic layer 3 and the second magnetic layer 4 by forming the former growth portions 3a, 4a formed of base end parts of the columns 5 by supplying oxygen gas to the deposition start point Ps of the deposition region A to grow the columns 5 in the thickness direction of the non-magnetic substrate 2 and forming the latter growth portions 3b, 4b formed of the remaining parts (i.e., front end parts) of the columns 5 by growing the columns 5 from the deposition start point Ps to the deposition end point Pe so as to become inclined to the longitudinal direction of the non-magnetic substrate 2 and arc-shaped in profile, it is possible to reliably and easily manufacture a magnetic tape 1 where the ratios of the thicknesses of the former growth portions 3a, 4a to the thicknesses of the latter growth portions 3b, 4b is in the desired range, or in other words, a magnetic tape 1 with the desired smoothness.

What is claimed is:

1. A magnetic recording medium comprising a first metal thin-film magnetic layer and a second metal thin-film magnetic layer, which respectively include a plurality of columns and have magnetization easy axes that are inclined in opposite directions, formed in the mentioned order on a non-magnetic substrate,
wherein both metal thin-film magnetic layers include former growth portions that comprise base end parts of the respective columns and latter growth portions that comprise remaining parts of the respective columns on front-end sides of the columns,
the former growth portions are formed by the columns growing in a thickness direction of the non-magnetic substrate, and
the latter growth portions are formed by the columns growing so as to become inclined to a longitudinal direction of the non-magnetic substrate and arc-shaped in profile.

2. A magnetic recording medium according to claim 1, wherein a ratio of a thickness of the first metal thin-film magnetic layer to a thickness of the second metal thin-film magnetic layer is in a range of 0.60 to 2.10, inclusive.

3. A magnetic recording medium according to claim 1, wherein a ratio of a thickness of the former growth portions to a thickness of the latter growth portions is in a range of 0.08 to 0.15, inclusive in both metal thin-film magnetic layers.

4. A magnetic recording medium manufacturing apparatus, comprising:
a rotating cooling drum that drives a non-magnetic substrate placed around a circumferential surface thereof while cooling the non-magnetic substrate;
a crucible that holds a metal material;
an electron gun that emits an electron beam toward the metal material inside the crucible to vaporize the metal material; and
a mask that is disposed along the circumferential surface of the rotating cooling drum and determines a deposition region where the metal material is deposited on the non-magnetic substrate,
wherein the magnetic recording medium manufacturing apparatus manufactures a magnetic recording medium by twice carrying out a depositing process that deposits the metal material on the non-magnetic substrate inside the deposition region to form a first metal thin-film magnetic layer and a second metal thin-film magnetic layer, which respectively include a plurality of columns and have magnetization easy axes that are inclined in opposite directions, in the mentioned order on the non-magnetic substrate,
the magnetic recording medium manufacturing apparatus further comprises an oxygen gas supplying unit that supplies oxygen gas to a deposition start point in the deposition region, and
during each depositing process, columns grow in a thickness direction of the non-magnetic substrate by supplying the oxygen gas from the oxygen gas supplying unit to the deposition start point to form former growth portions composed of base end parts of the respective columns, and from the deposition start point to a deposition end point in the deposition region, the columns grow so as to become inclined to a longitudinal direction of the non-magnetic substrate and arc-shaped in profile to form latter growth portions composed of remaining parts of the respective columns on the front-end sides of the columns.

5. A method of manufacturing a magnetic recording medium that manufactures a magnetic recording medium by forming a first metal thin-film magnetic layer and a second metal thin-film magnetic layer, which respectively include a plurality of columns and have magnetization easy axes that are inclined in opposite directions, in the mentioned order on a non-magnetic substrate by running the non-magnetic substrate around a circumferential surface of a rotating cooling drum and twice carrying out a depositing process that deposits vaporized metal material on the non-magnetic substrate within a deposition region set on the circumferential surface of the rotating cooling drum to consecutively form both metal thin-film magnetic layers,
wherein during each depositing process, the columns grow in a thickness direction of the non-magnetic substrate by supplying oxygen gas to a deposition start point in the deposition region to form former growth portions composed of base end parts of the columns, and from the deposition start point to a deposition end point, the columns grow so as to become inclined to a longitudinal direction of the non-magnetic substrate and arc-shaped in profile to form latter growth portions composed of remaining parts of the columns on the front-end sides of the columns.
